(19) United States
(12) Patent Application Publication
(10) Pub. No.: US 2026/0298672 A1
(43) Pub. Date: Oct. 1, 2026

(54) FILTERING PHOTODETECTOR FOR USE IN OPTICAL ENCODERS

(71) Applicant: Novanta Corporation, Bedford, MA (US)

(72) Inventor: William G. Thorburn, Danvers, MA (US)

(21) Appl. No.: 19/632,012

(22) Filed: Mar. 27, 2026

Related U.S. Application Data
(60) Provisional application No. 63/778,873, filed on Mar. 27, 2025.
(60) Provisional application No. 63/778,871, filed on Mar. 27, 2025.

(51) Int. Cl. G01D 5/30; H10F 30/223; H10F 39/10; H10F 77/14; H10F 77/20; H10F 77/30

(52) U.S. Cl. CPC G01D 5/30; H10F 30/223; H10F 39/107; H10F 77/147; H10F 77/148; H10F 77/241; H10F 77/334

(57) ABSTRACT

A photodetector for an optical encoder includes a semiconductor die, the semiconductor die including a plurality of doped regions disposed over an oppositely-doped substrate, the doped regions laterally spaced apart from one another and forming respective photodiodes with the substrate. The semiconductor die further includes a light-receptive semiconductor region laterally adjacent to a first doped region of the plurality of doped regions, the first doped region forming a first photodiode with the substrate. The light-receptive semiconductor region is constructed and arranged to respond to illumination by stimulating current flow in the first photodiode, thereby at least partially filtering transient changes in current through the first photodiode in response to optical transients crossing an edge of the first doped region.

### CROSS-REFERENCE TO RELATED APPLICATIONS

This application claims the benefit of the following U.S. Provisional Patent Applications:
1. Application No. 63/778,873, filed Mar. 27, 2025 and entitled “ROTARY OPTICAL ENCODER WITH ROTATING ANGLE-ENCODING LIGHT PATTERN.”
2. Application No. 63/778,871, filed Mar. 27, 2025 and entitled “FILTERING PHOTODETECTOR FOR USE IN OPTICAL ENCODERS.”

The contents and teachings of both of the above applications are incorporated by reference herein in their entirety.

### BACKGROUND

Optical encoders are electromechanical devices for accurately measuring rotational or linear movement of one part of a machine relative to another. A typical optical encoder includes two parts, with each part of the encoder attached to a respective part of the machine. A first part of the encoder includes a light source, such as an LED (light-emitting diode) or a laser, such as a Vertical-Cavity Surface-Emitting Laser (VCSEL), a photodetector, and electronic control circuitry. A second part of the encoder is moveable relative to the first part, and relative movement of the two parts causes a varying pattern of light from the light source to fall on the photodetector. By capturing output from the photodetector, displacement between the two parts of the encoder can be accurately measured.

Some photodetectors include an array of photodiodes. For example, a photodetector in a rotary encoder (for measuring angles) can include multiple photodiodes arranged around a ring. The encoder projects a pattern of light onto the photodetector, and the pattern rotates around the ring as the two parts of the encoder rotate relative to each other. Each of the individual photodiodes around the ring measures the varying pattern, which repeats for every rotation of the first part relative to the second part. The use of multiple photodiodes around the ring increases angular resolution and improves accuracy.

### SUMMARY

Certain embodiments are directed to a photodetector for an optical encoder, the photodetector including a semiconductor die. The semiconductor die includes a plurality of doped regions disposed over an oppositely-doped substrate, the doped regions laterally spaced apart from one another and forming respective photodiodes with the substrate. The semiconductor die further includes a light-receptive semiconductor region laterally adjacent to a first doped region of the plurality of doped regions, the first doped region forming a first photodiode with the substrate. The light-receptive semiconductor region is constructed and arranged to respond to illumination by stimulating current flow in the first photodiode, thereby at least partially filtering changes in current through the first photodiode in response to illumination crossing an edge of the first doped region.

Other embodiments are directed to a method of operating a photodetector, such as the photodetector described above. The method includes varying a reverse-bias voltage applied to the first photodiode to vary a sensitivity of the first photodiode to the transient changes in illumination crossing edges of the first doped region.

Still further embodiments are directed to an optical encoder. The optical encoder includes a first part that includes a light source and a photodetector, and a second part that is moveable relative to the first part. The second part includes an optic configured to project an illuminated pattern onto the photodetector based on light from the light source. The photodetector includes a semiconductor. The semiconductor includes a plurality of doped regions disposed over an oppositely-doped substrate. The doped regions are laterally spaced apart from one another and form respective photodiodes with the substrate. The semiconductor die further includes a light-receptive semiconductor region laterally adjacent to a first doped region of the plurality of doped regions, the first doped region forming a first photodiode with the substrate. The light-receptive semiconductor region is constructed and arranged to respond to illumination by stimulating current flow in the first photodiode.

The foregoing summary is presented for illustrative purposes to assist the reader in readily grasping example features presented herein; however, this summary is not intended to set forth required elements or to limit embodiments hereof in any way. One should appreciate that the above-described features can be combined in any manner that makes technological sense, and that all such combinations are intended to be disclosed herein, regardless of whether such combinations are identified explicitly or not.

### BRIEF DESCRIPTION OF THE SEVERAL VIEWS OF THE DRAWINGS

The foregoing and other features and advantages will be apparent from the following description of particular embodiments, as illustrated in the accompanying drawings, in which like reference characters refer to the same or similar parts throughout the different views. The drawings are not necessarily to scale, emphasis instead being placed upon illustrating the principles of various embodiments.

FIG. 1 is a side view of an optical encoder according to one or more embodiments.

FIG. 2 is a plan view of a reflective optic which may be used in the optical encoder of FIG. 1, according to one or more embodiments.

FIG. 3 is a cross-sectional view of a semiconductor die of a photodetector of FIG. 1, according to one or more embodiments.

FIG. 4 is a cross-sectional view of an alternative semiconductor die of a photodetector of FIG. 1, according to one or more embodiments.

FIG. 5 is a circuit diagram of example electronic circuitry of the optical encoder of FIG. 1, according to one or more embodiments.

FIG. 6 is a top plan view of an example photodetector suitable for use in the optical encoder of FIG. 1, according to one or more embodiments.

FIG. 7 is a top plan view of an example photodetector having light-receptive regions disposed between doped regions, according to one or more embodiments.

FIG. 8 is a top plan view of an example photodetector having large light-receptive regions disposed between doped regions, according to one or more embodiments.

FIG. 9 is a top plan view of an example photodetector having concentric rings of doped regions and a middle ring of light-receptive regions, according to one or more embodiments.

FIG. 10 is a top plan view of an example photodetector having masked concentric rings of doped regions and a middle ring of light-receptive regions, according to one or more embodiments.

### DETAILED DESCRIPTION

Known optical encoders can achieve precise measurements of angular or linear displacement. However, measurement errors can arise due to imperfections. For example, dust or other particles can enter an optical system of the encoder, causing dark spots to appear in the pattern of light projected onto the photodetector. A dark spot can cause a sudden change in output current from a photodiode when the dark spot transitions across an edge of the photodiode’s light-collecting surface. For example, the photodiode may see a sudden drop in incident light when the dark spot enters the light-collecting surface and may see a sudden jump in incident light when the dark spot exits the light collecting surface.

In a rotary encoder having multiple photodiodes arranged in a ring, a dark spot may appear as high-frequency harmonic components at multiples of a fundamental frequency, which typically corresponds to a complete rotation of the first part of the encoder relative to the second part. Low-frequency errors in encoders can be corrected using lookup tables, but high-frequency errors such as those produced by dark spots are more difficult to correct. A better approach would be to reduce the effects of optical imperfections at the source. What is needed, therefore, is a photodetector that inherently suppresses sudden changes in output currents of photodiodes caused by optical imperfections.

The above need is addressed at least in part with an improved technique that provides a photodetector having a semiconductor die that includes a plurality of doped regions disposed over an oppositely-doped substrate, such that the doped regions form respective photodiodes with the substrate. The semiconductor die further includes a set of light-receptive semiconductor regions, composed of substrate or undoped (intrinsic) semiconductor material adjacent to the doped regions. When exposed to incoming light, the light-receptive regions produce charge carriers, and some of the charge carriers drift to depletion regions of nearby photodiodes, increasing their current flow. Changes in current are greater for parts of the light-receptive regions that are closer to the depletion regions than for parts that are farther away. The effect of placing light-receptive regions adjacent to the doped regions effectively reduces transient changes in photodiode currents as light transients (e.g., dark spots or bright spots) cross edges of the doped regions, resulting in a spatial smoothing or filtering effect.

Advantageously, the improved technique softens the effects of dark spots and other optical imperfections. In a rotary photodetector array, for example, the improved technique can reduce the amplitudes and/or lower the frequencies of edge-crossing distortions, rendering them less significant or moving them to lower frequencies, where they can easily be corrected using lookup tables or related approaches.

According to one or more embodiments, a size and/or doping concentration of the doped regions may be varied to achieve desired performance characteristics. Also, a reverse bias voltage applied across the photodiodes may be varied to improve blending of the photosensitivity of depletion regions with the photosensitivity of light-receptive semiconductor regions.

According to one or more embodiments, intrinsic semiconductor material is placed between the doped regions and the substrate, such that the photodiodes form PIN (Positive-Intrinsic-Negative) or NIP (Negative-Intrinsic-Positive) photodiodes having enlarged depletion regions. The intrinsic depth may be varied to achieve desired characteristics.

According to one or more embodiments, the photodiodes can be arranged in various geometries. Linear arrays (for linear encoders) can include multiple doped regions arranged in a line, whereas rotary arrays (for angular encoders) can include multiple doped regions arranged around a ring. In both arrangements, depletion regions may be formed with light-receptive semiconductor regions placed between adjacent doped regions, or placed alongside the doped regions. In some arrangements, a light-receptive semiconductor region is placed concentrically inside a ring of doped regions, and/or concentrically outside such a ring. In further arrangements, two concentric rings of doped material may be formed, with a ring of light-receptive semiconductor material placed radially between the two rings of doped regions. Also, individual photodiodes can be reduced in size and grouped to form channels, where each channel includes a parallel combination of multiple photodiodes. Photodiodes from different channels can be interleaved and blended such that each channel covers a respective angular range of the ring and overlaps with the angular ranges covered by other channels. In still further arrangements, the doped regions, or some portions or subsets of them, can be masked from incident light, while the light-receptive semiconductor regions are exposed to light, resulting in a strong smoothing effect.

Embodiments of the improved technique will now be described. One should appreciate that such embodiments are provided by way of example to illustrate certain features and principles but are not intended to be limiting.

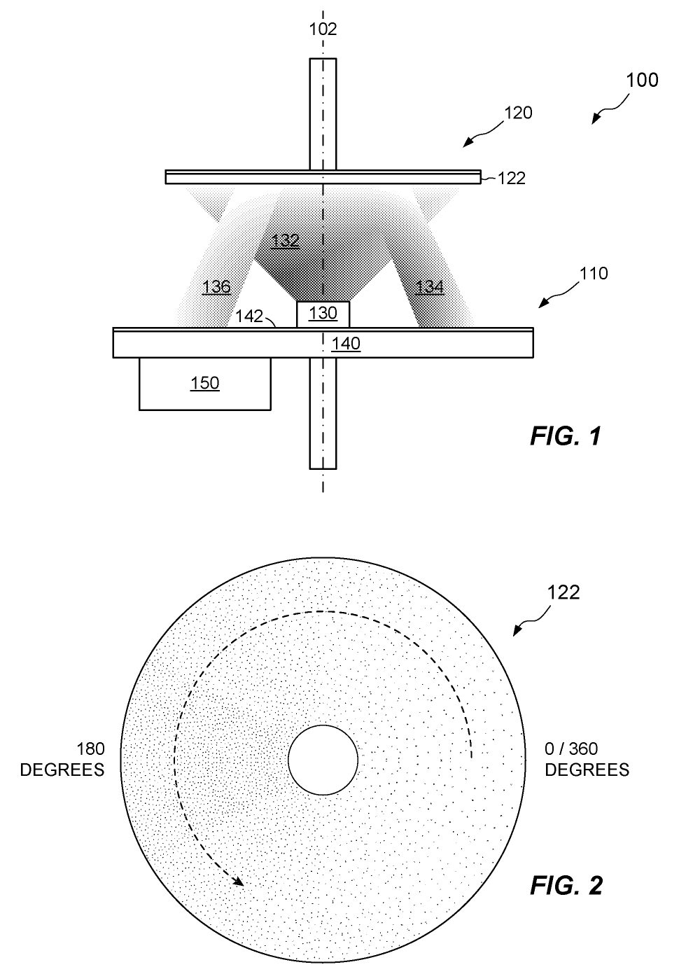

FIG. 1 is a simplified side view of an optical encoder 100 according to one or more embodiments. The depicted encoder 100 is a rotary encoder; however, other embodiments may include linear encoders. The encoder 100 includes a first part 110 and a second part 120. The first part 110 and the second part 120 are rotatable relative to each other about an axis 102. The first part 110 includes a light source 130, such as a LED or laser (e.g., a VCSEL), a disc-shaped photodetector 140, and electronic control circuitry 150, such as a power source for powering the light source 130 and other electronics, measurement circuitry for reading the photodetector 140, and communication circuitry for transmitting photodetector readings to outside equipment. According to one or more embodiments, the photodetector 140 includes a single semiconductor die 142 that includes all photodiodes used by the photodetector 140. For example, the semiconductor die 142 may be disc-shaped. Other arrangements are possible, however, such as multiple semiconductor dies. The second part 120 includes an optic 122, such as a patterned reflector; however, other types of optics may alternatively be used for transmissive encoders. The first part 110 and the second part 120 may be contained within a housing (not shown), which spaces apart the first and second parts 110 and 120 and holds them in proper alignment with the axis 102. The depiction of FIG. 1 is intended to be simplified, as practical encoders may include additional components, such as one or more lenses and/or light diffusers, for example.

In example operation, the encoder 100 is attached to a machine, such that the axis 102 of the encoder 100 aligns with an axis of rotation between first and second parts of the machine. As the first and second parts of the machine rotate relative to each other, the first and second parts 110 and 120 of the encoder 100 rotate relative to each other correspondingly.

The light source 130 projects a light cone 132 upwardly. Light from the light cone 132 hits the optic 122 and reflects back down to the photodetector 140, which measures the reflected light. In an example, the optic 122 is constructed and arranged to reflect light from the light cone 132 in a non-uniform pattern. For instance, a first reflected beam 134 may be brighter than a second reflected beam 136. The difference in brightness enables the encoder 100 to measure angles of rotation of the first part 110 relative to the second part 120 with high resolution and accuracy.

FIG. 2 shows an example optic 122 according to one or more embodiments. The depicted view in FIG. 2 is looking up from the perspective of the light source 130 of FIG. 1. It can be seen that the optic 122 has a reflective surface that varies in reflectivity, in this example starting with low reflectivity at 0 degrees, reaching a maximum reflectivity at 180 degrees, and then returning to the low reflectivity at 360 degrees. In one example, the change in reflectivity of the optic 122 versus angle is sinusoidal, which enables certain mathematical enhancements to be used when processing outputs from the photodetector 140.

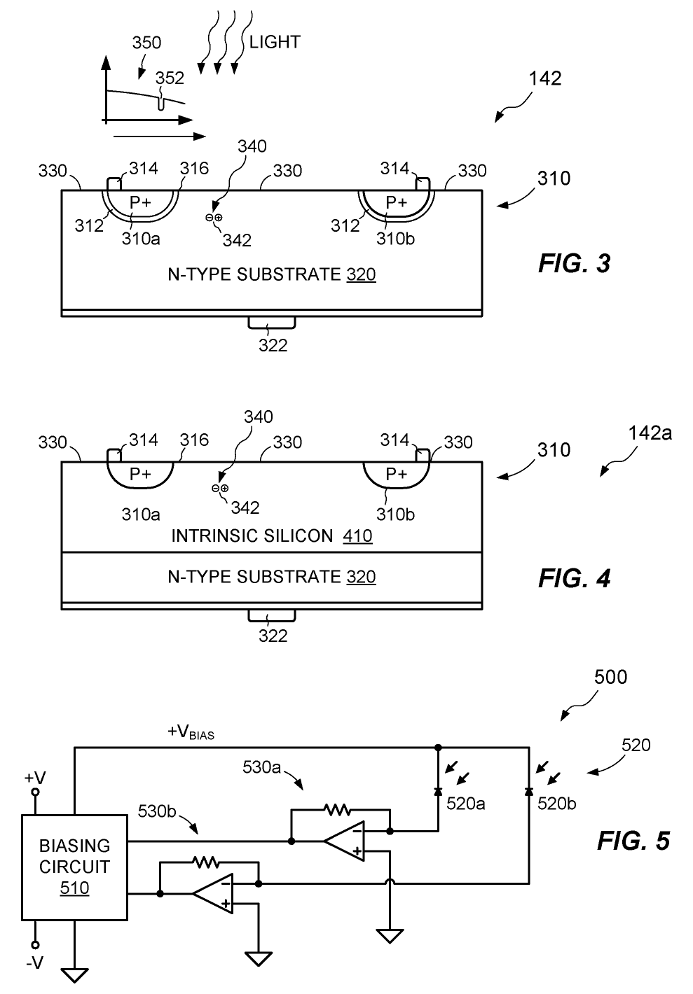

FIG. 3 shows an example semiconductor die 142 or portion thereof, according to one or more embodiments. The semiconductor die 142 includes multiple doped regions 310, such as a first doped region 310a and a second doped region 310b, which are formed within a substrate 320. In the illustrated example, the doped regions 310 are P+ regions and the substrate is N-type. Other arrangements are possible, however, such as NIP arrangements, which provide N-doped regions and a P+ substrate.

The doped regions 310 form respective photodiodes with the substrate 320. For example, depletion regions 312 arise at boundaries between the doped regions 310 and the substrate 320. When the photodiodes are reverse-biased, the depletion regions 312 become highly photosensitive, such that light falling upon the depletion regions 312 efficiently induces reverse currents through the photodiodes. Each photodiode is defined by an anode and a cathode. The anode of each photodiode is formed by a contact 314, which is electrically coupled to a respective doped region 310. The cathode in this example is common to all photodiodes and may be formed by a contact 322, which is electrically coupled to the substrate 320. Electrical connections may be made to the contacts 314, 322 using wire bonds, for example.

In the example shown, the doped regions 310 are disposed adjacently to light-receptive semiconductor regions 330, which may be provided as one continuous light-receptive region or as multiple distinct regions. The light-receptive character of the regions 330 enables them to be exposed to incident light, such as light reflected from the optic 122 (FIG. 1).

We have observed that the light-receptive regions 330, composed in this example of N-type substrate material, are also photosensitive, but to a lesser degree than the depletion regions 312. For example, a photon 340 hitting a light-receptive region 330 may generate an electron-hole pair 342. Charge carriers produced thereby may drift to a nearby depletion region 312, where they induce additional current flow through the associated photodiode. Light hitting the light-receptive regions 330 closer to a depletion region 312 induces greater current flow than light hitting farther away. The effect of the light-receptive regions 312 is thus to soften the edges of the doped regions 310, effectively spreading out those edges in space and tapering them down over distance. One should appreciate that the light-receptive regions 330 may be completely exposed to light (unmasked) or partially masked, e.g., covered by a semi-transparent mask material. Opacity of such mask material may be varied to achieve desired levels of photosensitivity in the light-receptive regions 330.

Consider, for example, an illumination pattern 350 that moves across the upper surface of the semiconductor die 142, e.g., based on rotation of the optic 122 (FIG. 1). The vertical axis of the illumination pattern 350 represents light intensity, and the horizontal axis represents spatial location. Assume that the illumination pattern 350 includes a dark spot 352, which corresponds to a dust mote or other obstacle. When the dark spot 352 crosses an edge 316 of the doped region 310a, the dark spot 352 would normally cause a sudden and substantial drop in light measured by the photodiode. But because the light-receptive regions 330 are adjacent to the edge 316, additional current flow is sustained outside the edge 316 (as the dark spot 352 moves to the right), such that the normally expected drop-off in photodiode current is muted. Given that the current flow from the light-receptive regions 330 is greatest directly adjacent to the edge 316 (where the depletion region 312 ends) and tapers off with distance, the light-receptive regions 330 provide spatial filtering such that the effects of the dark spot 352 are reduced. The same spatial filtering can occur at any edge of any of the doped regions 310, provided that the edge is adjacent to a light-receptive region 330.

Various adjustments can be made in the semiconductor die 142 to vary its behavior. The doped regions 310 can be made bigger or smaller. Doping concentrations may be adjusted. Also, the density of impurities other than doping materials may be varied. For example, a photosensitivity of the light-receptive semiconductor regions 330 is variable based on an impurity density of the light-receptive semiconductor region 330. Also, reverse-bias voltages applied to the photodiodes can be varied. For example, increasing reverse-bias voltage widens the depletion regions 312, making them more photosensitive, while decreasing reverse-bias voltage reduces photosensitivity. However, some embodiments aim to minimize reverse-bias voltage to help smooth transitions in photosensitivity between the depletion regions 312 and the adjacent light-receptive regions 330, resulting in an overall improvement in performance.

One should appreciate that conventional photodiode arrays aim to minimize crosstalk between different photodiodes. However, embodiments of the technique presented herein actually encourage controlled amounts of crosstalk, by providing photosensitive light-receptive regions 330 adjacent to different doped regions 310.

FIG. 4 shows an alternative semiconductor die 142a, according to one or more embodiments. The semiconductor die 142a is similar to the one shown in FIG. 3, except that the semiconductor die 142a includes intrinsic semiconductor material 410 between the doped regions 310 and the substrate 320, such as a layer of intrinsic material. In an example, the intrinsic semiconductor material 410 is a layer of pure silicon. Incident light hitting the light-receptive intrinsic material generates electron-hole pairs 342, as in FIG. 3. Inclusion of intrinsic material 410 enlarges the depletion regions 312 formed around the doped regions 310, which may extend across the entire intrinsic layer 410, increasing the photosensitivity of the light-receptive regions 330.

FIG. 5 shows an example electronic circuit 500 suitable for use with the semiconductor dies 142 and 142a, according to one or more embodiments. Here, a biasing circuit 510 applies a reverse-bias voltage across photodiodes 520, such as photodiodes 520a and 520b. For example, photodiode 520a may be formed between doped region 310a and the substrate 320 (FIG. 3) and photodiode 520b may be formed between doped region 310b and the substrate 320. In the example shown, which is not intended to be limiting, biasing circuit 510 applies a positive voltage V_{BIAS} to the cathodes of the photodiodes 520a and 520b, with the anodes of the photodiodes 520a and 520b connected to virtual grounds. Amplifiers 530a and 530b convert the currents from photodiodes 520a and 520b to respective voltages, which can be digitized by one or more analog-to-digital converters (not shown). In some examples, the biasing circuit 510 is programmable for generating a variable bias voltage V_{BIAS}, enabling bias voltage to be tuned for achieving desired performance characteristics.

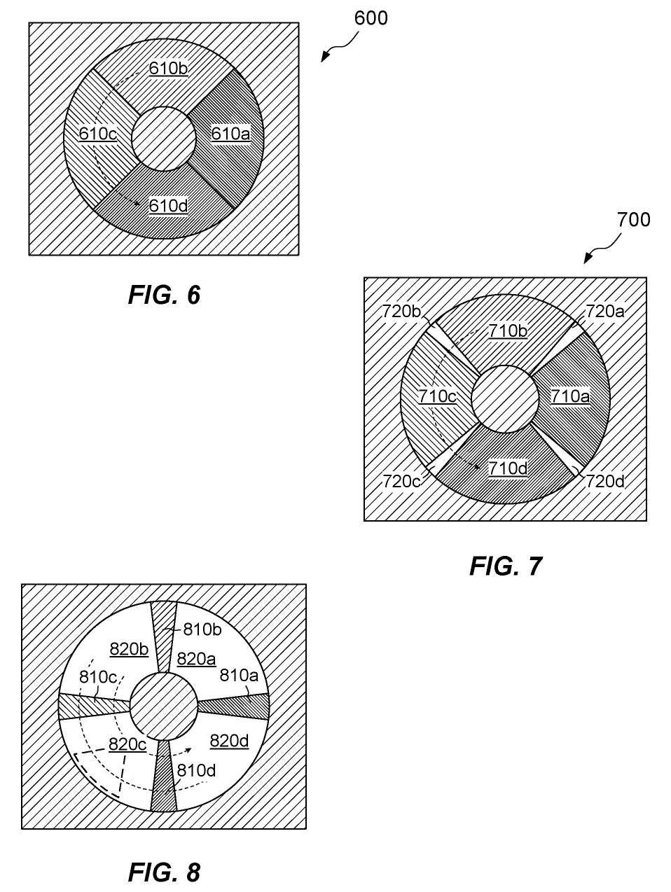

FIG. 6 shows an example photodetector 600 arranged in four quadrants 610, i.e., 610a, 610b, 610c, and 610d, where the four quadrants 610 depict respective photodiode channels. The photodetector 600 does not benefit from the use of light-receptive regions 330. Rather, each quadrant is completely filled with a doped region 310 of a respective photodiode. Dark spots and other disturbances that cross edges in the photodetector 600 may cause noticeable errors.

In contrast, FIG. 7 shows an example photodetector 700 according to one or more embodiments. Here, doped regions 710a, 710b, 710c, and 710d leave space for light-receptive regions 330, shown here as regions 720a, 720b, 720c, and 720d. The FIG. 7 arrangement encourages crosstalk between channels and softens response profiles at ends of each photodiode, helping to minimize sensitivity to high spatial frequencies.

FIG. 8 takes the FIG. 7 idea further by providing smaller doped regions 810a, 810b, 810c, and 810d and providing larger light-receptive regions 820a, 820b, 820c, and 820d. Providing large light-receptive regions makes the photodetector’s response along any circular path pseudo-sinusoidal, which may provide performance advantages.

A limitation of the FIG. 8 approach, however, is that different response profiles are produced at different radii. Near an inner diameter the response might resemble an approximate sinusoid to some extent, but toward the outer diameter the response will be poorer in the wide light-receptive regions. This effect might be partially remedied by increasing the width of the doped regions non-linearly as a function of radius, i.e., by making the width of a doped region increasingly wider than a simple wedge shape would be (e.g., by curving the edges of the flared doped regions outward). But this sort of design can provide only a rough approximation of sinusoidal response.

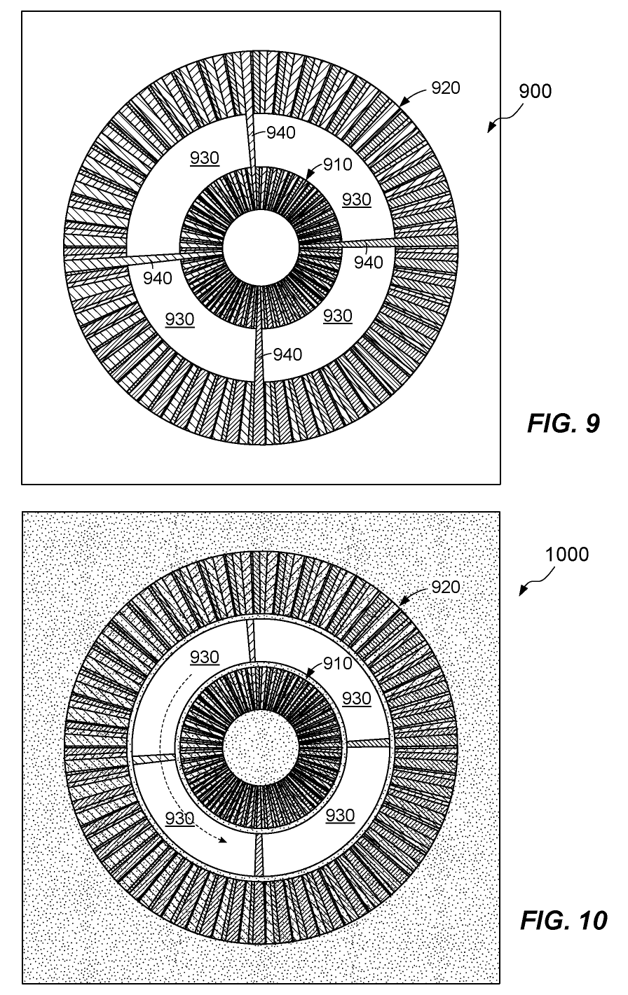

FIG. 9 shows yet another arrangement 900. Here, doped regions 310 of different channels are shown with different shading. Four channels are present, with wedge-shaped doped regions of one channel interleaved with wedge-shaped doped regions of other channels. In an example, interleaved doped regions 310 have sinusoidally varying widths. The varying widths are designed for sinusoidal response profiles that are phase shifted with respect to each other at 90 degrees. For example, arc lengths of doped regions 310 in each channel vary sinusoidally with azimuth angle (around the rings), and the arc length of doped regions in one quadrant has different phase from a respective arc length of doped regions in each other channel of the multiple channels.

Inner and outer rings 910 and 920 of doped regions are shown, with each ring having the same pattern of wedges. A large light-receptive area 930 forms a middle ring between inner and outer rings 910 and 920. Within the rings 910 and 920, same-channel doped regions are electrically connected in parallel, e.g., using copper traces or doped semiconductor material (having the same doping as the doped regions 310). Also, doped regions of inner ring 910 are connected via ribs 940 to same-channel doped regions of outer ring 920. For these connections, doped semiconductor material is preferred over copper, as photosensitivity of doped semiconductor material more closely matches that of the light-receptive region 930 than would copper. With the FIG. 9 arrangement, photons incident upon the light-receptive region (or regions) 930 induce current in each channel proportional to the widths of the adjacent doped regions in the inner and outer rings 910 and 920.

FIG. 10 shows yet another arrangement 1000. FIG. 10 is similar to FIG. 9, except that the doped regions of the inner and outer rings 910 and 920 are masked, e.g., covered with metal or polymer, such that they receive no direct light exposure. The mask is shown semi-transparently for clarity. By masking doped regions as shown, the light-receptive ring 930 is left exposed to incident light. Along a circular path within that exposed ring, the photo response will be nearly sinusoidal since photons incident in that region will generate current in the adjacent (but masked) doped regions in proportions determined by the relative widths of the doped regions.

An improved technique has been described for providing a photodetector 140 for use in an optical encoder 100. The photodetector 140 includes a semiconductor die 142, 142a that includes a plurality of doped regions 310 disposed over an oppositely-doped substrate 320, such that the doped regions 310 form respective photodiodes 520 with the substrate 320. The semiconductor die further includes a set of light-receptive semiconductor regions 330, composed of substrate 320 or undoped (intrinsic) material 410 adjacent to the doped regions 310. When exposed to incoming light, the light-receptive regions 330 produce charge carriers 342, and some of the charge carriers 342 drift to depletion regions 310 of nearby photodiodes 520, increasing their current flow. Changes in current are greater for parts of the light-receptive regions 330 that are closer to the depletion regions 312 than for parts that are farther away. The effect of placing light-receptive regions 330 adjacent to the doped regions 310 effectively reduces transient changes in photodiode currents as light transients (e.g., dark spots) cross edges 316 of the doped regions 310, resulting in a spatial filtering effect.

Having described certain embodiments, numerous alternative embodiments or variations can be made. For example, although embodiments have been described in which a photodetector includes an array of multiple photodiodes, this is just an example. Alternatively, a photodetector can include only a single photodiode, for which edge transitions of optical defects are smoothed by proximity to a light-receptive semiconductor region 330. Further, although features have been shown and described with reference to particular embodiments hereof, such features may be included and hereby are included in any of the disclosed embodiments and their variants. Thus, it is understood that features disclosed in connection with any embodiment are included in any other embodiment.

As used throughout this document, the words “comprising,” “including,” “containing,” and “having” are intended to set forth certain items, steps, elements, or aspects of something in an open-ended fashion. Also, as used herein and unless a specific statement is made to the contrary, the word “set” means one or more of something. This is the case regardless of whether the phrase “set of” is followed by a singular or plural object and regardless of whether it is conjugated with a singular or plural verb. Also, a “set of” elements can describe fewer than all elements present. Thus, there may be additional elements of the same kind that are not part of the set. Further, ordinal expressions, such as “first,” “second,” “third,” and so on, may be used as adjectives herein for identification purposes. Unless specifically indicated, these ordinal expressions are not intended to imply any ordering or sequence. Thus, for example, a “second” event may take place before or after a “first event,” or even if no first event ever occurs. In addition, an identification herein of a particular element, feature, or act as being a “first” such element, feature, or act should not be construed as requiring that there must also be a “second” or other such element, feature or act. Rather, the “first” item may be the only one. Also, and unless specifically stated to the contrary, “based on” is intended to be nonexclusive. Thus, “based on” should be interpreted as meaning “based at least in part on” unless specifically indicated otherwise. Further, although the term “user” as used herein may refer to a human being, the term is also intended to cover non-human entities, such as robots, bots, and other computer-implemented programs and technologies. Although certain embodiments are disclosed herein, it is understood that these are provided by way of example only and should not be construed as limiting.

Those skilled in the art will therefore understand that various changes in form and detail may be made to the embodiments disclosed herein without departing from the scope of the following claims.

What is claimed is:

1. A photodetector for an optical encoder, the photodetector including a semiconductor die, the semiconductor die comprising:
a plurality of doped regions disposed over an oppositely-doped substrate, the doped regions laterally spaced apart from one another and forming respective photodiodes with the substrate; and
a light-receptive semiconductor region laterally adjacent to a first doped region of the plurality of doped regions, the first doped region forming a first photodiode with the substrate,
wherein the light-receptive semiconductor region is constructed and arranged to respond to illumination by stimulating current flow in the first photodiode, thereby at least partially filtering changes in current through the first photodiode in response to illumination crossing an edge of the first doped region.

2. The photodetector of claim 1, wherein a photosensitivity of the light-receptive semiconductor region is variable based on a reverse-bias voltage applied to the first photodiode.

3. The photodetector of claim 1, wherein the first photodiode forms a depletion region, and wherein a photosensitivity of the light-receptive semiconductor region is variable based on a proximity to the depletion region.

4. The photodetector of claim 1, wherein a photosensitivity of the light-receptive semiconductor region is variable based on a doping density of the light-receptive semiconductor region.

5. The photodetector of claim 1, wherein a photosensitivity of the light-receptive semiconductor region is variable based on an impurity density of the light-receptive semiconductor region.

6. The photodetector of claim 1, wherein light-receptive semiconductor region is covered by a partially-transparent mask, and wherein a photosensitivity of the light-receptive semiconductor region is variable based on the opacity of the partially-transparent mask.

7. The photodetector of claim 1, wherein the semiconductor die further comprises intrinsic semiconductor material between the plurality of doped regions and the oppositely-doped substrate, the intrinsic semiconductor material forming the light-receptive semiconductor region adjacent to the first doped region.

8. The photodetector of claim 1, wherein the plurality of doped regions further includes a second doped region, and wherein the light-receptive semiconductor region is disposed between the first and second doped regions.

9. The photodetector of claim 8, wherein the doped regions are arranged along at least one of (i) a line, (ii) a ring, or (iii) a partial ring.

10. The photodetector of claim 8, wherein the doped regions are arranged along a ring or partial ring, and wherein the semiconductor die further comprises a respective light-receptive semiconductor region disposed between each pair of doped regions around the ring or partial ring.

11. The photodetector of claim 10, wherein each light-receptive semiconductor region has an area greater than an area of any of the doped regions.

12. The photodetector of claim 1, wherein the optical encoder is a rotary encoder, and wherein the plurality of doped regions is grouped into multiple channels, with each channel including multiple doped regions connected together in parallel using metal or semiconductor material.

13. The photodetector of claim 12, wherein a first set of the plurality of doped regions is arranged in a first ring, wherein a second set of the plurality of doped regions is arranged in a second ring concentric with the first ring, and wherein the light-receptive semiconductor region is radially disposed between the first set of doped regions in the first ring and the second set of doped regions in the second ring.

14. The photodetector of claim 12, wherein the first set of doped regions and the second set of doped regions each include at least one doped region from each of the channels.

15. The photodetector of claim 14, wherein the semiconductor die further includes a plurality of doped ribs, each of the plurality of doped ribs connecting a doped region of a respective channel in first set of doped regions to a doped region of the same respective channel in the second set of doped regions.

16. The photodetector of claim 14, wherein the first set of doped regions in the first ring is an interleaved pattern of doped regions of different channels.

17. The photodetector of claim 16, wherein the first ring has multiple quadrants, and where each of the quadrants has a respective unique combination of doped regions from among the channels.

18. The photodetector of claim 17, wherein arc lengths of doped regions in each channel vary sinusoidally with azimuth angle, and wherein an arc length of doped regions in one quadrant has different phase from a respective arc length of doped regions in each other channel of the multiple channels.

19. The photodetector of claim 13, wherein the semiconductor die includes a mask that at least partially blocks light from reaching the plurality of doped regions or a portion thereof.

20. A method of operating the photodetector of claim 1, comprising:
varying a reverse-bias voltage applied to the first photodiode to vary a sensitivity profile of the first photodiode to illumination crossing edges of the first doped region.

21. An optical encoder, comprising:
a first part that includes a light source and a photodetector; and
a second part that is moveable relative to the first part, the second part including an optic configured to project an illuminated pattern onto the photodetector based on light from the light source,
wherein the photodetector includes a semiconductor, the semiconductor including:
a plurality of doped regions disposed over an oppositely-doped substrate, the doped regions laterally spaced apart from one another and forming respective photodiodes with the substrate; and
a light-receptive semiconductor region laterally adjacent to a first doped region of the plurality of doped regions, the first doped region forming a first photodiode with the substrate,
wherein the light-receptive semiconductor region is constructed and arranged to respond to illumination by stimulating current flow in the first photodiode.

22. The optical encoder of claim 21, wherein the semiconductor further comprises intrinsic semiconductor material between the plurality of doped regions and the oppositely-doped substrate, the intrinsic semiconductor material forming the light-receptive semiconductor region adjacent to the first doped region.
